(19) United States
(12) Patent Application Publication
(10) Pub. No.: US 2023/0321680 A1
(43) Pub. Date: Oct. 12, 2023

(54) PROCESSING APPARATUS

(71) Applicant: DISCO CORPORATION, Tokyo (JP)

(72) Inventor: Satoshi YAMANAKA, Tokyo (JP)

(21) Appl. No.: 18/295,926

(22) Filed: Apr. 5, 2023

(30) Foreign Application Priority Data
Apr. 12, 2022 (JP) 2022-065474

(51) Int. Cl. B05B 13/02; B05B 14/30; B05B 15/555

(52) U.S. Cl. CPC B05B 13/0242; B05B 14/30; B05B 15/555; B08B 3/02

(57) ABSTRACT

A processing apparatus includes a processing chamber cover having a first transverse member extending from between a first side plate and a first delivery port defined in the first side plate outwardly of a first processing chamber. The width of a gap between the first transverse member and a pedestal positioned in the first delivery port when a workpiece is processed in the first processing chamber, i.e., the length of the gap along the direction toward the outside of the processing chamber, is large. When processing water that is scattered passes through the gap, the processing water will likely contact the pedestal or the first transverse member and stay in the gap. As a result, the processing water is effectively prevented from being scattered out of the first processing chamber by a simple structure, compared with water supply means for forming a water film in the gap.

### BACKGROUND OF THE INVENTION

### Field of the Invention

The present invention relates to a processing apparatus for processing a workpiece in a processing chamber.

### Description of the Related Art

Chips containing devices such as integrated circuits (ICs) are indispensable components in various electronic appliances such as cellular phones or personal computers. Such chips are manufactured according to the following sequence of steps.

First, a number of elements are formed on a face side of a workpiece such as a wafer by photolithography and other techniques, producing a plurality of devices on the workpiece. Then, the workpiece is thinned down by grinding a reverse side of the workpiece. Then, the workpiece is divided into a plurality of chips by cutting the workpiece along boundaries between the devices.

A processing apparatus for use in fabrication of chips include a grinding apparatus for grinding a workpiece, a cutting apparatus for cutting a workpiece, and another apparatus. A processing apparatus processes a workpiece while the workpiece is being held on a chuck table. When the workpiece processed, it produces swarf. If the swarf is attached to the workpiece, quality of chips to be fabricated from the workpiece is likely to be lowered.

Generally, the processing apparatus includes a processing chamber in which the chuck table for holding the workpiece thereon is positioned. The workpiece on the chuck table is processed while the workpiece is being supplied with processing water to wash the swarf off the workpiece. The processing chamber defines therein a space surrounded by a processing chamber cover. The processing chamber cover includes a side plate having a delivery port through which the chuck table that is holding the workpiece can be delivered to or out the processing chamber.

While the workpiece on the chuck table in the processing chamber is being processed, the processing chamber may not necessarily be fully closed, but the delivery port, for example, may be kept open. With the delivery port being open, the processing water may be scattered through the delivery port or the like when the workpiece is processed in the processing chamber. To alleviate the difficulty, there has been proposed a processing apparatus including a seal mechanism that seals a delivery port in a side wall of a processing chamber cover when a workpiece is processed in a processing chamber (see, for example, JP 2012-76171A).

Specifically, the seal mechanism has water supply means for supplying water to a gap between the upper surface of a pedestal that is positioned in the delivery port when the workpiece is processed in the processing chamber and the lower surface of the side wall of the processing chamber cover that faces the upper surface of the pedestal. The delivery port is sealed by a water film created when water is supplied from the water supply means to the gap.

### SUMMARY OF THE INVENTION

However, the seal mechanism including the water supply mechanism is liable to make the processing apparatus complex in structure and increase a cost with which to manufacture the processing apparatus. It is therefore an object of the present invention to provide a processing apparatus having a simple structure for preventing processing water from being scattered outwardly of a processing chamber.

In accordance with an aspect of the present invention, there is provided a processing apparatus for processing a workpiece in a first processing chamber. The processing apparatus includes a chuck table for holding the workpiece thereon, a processing chamber cover having a first side plate with a first delivery port defined therein to allow the chuck table that is holding the workpiece to be delivered therethrough into and out of the first processing chamber, a first processing unit for processing the workpiece delivered into the first processing chamber with a first processing tool, a first processing water supply unit for supplying first processing water to at least one of the workpiece or the first processing tool when the workpiece is processed in the first processing chamber, and a pedestal positioned in the first delivery port when the workpiece is processed in the first processing chamber, in which the processing chamber cover includes a first transverse member extending from between the first side plate and the first delivery port outwardly of the first processing chamber.

Preferably, the processing apparatus is arranged for processing the workpiece in a second processing chamber in addition to the first processing chamber, and further includes a second processing unit for processing the workpiece delivered into the second processing chamber with a second processing tool, and a second processing water supply unit for supplying second processing water to at least one of the workpiece or the second processing tool when the workpiece is processed in the second processing chamber, in which the processing chamber cover has a second side plate with a second delivery port defined therein to allow the chuck table that is holding the workpiece to be delivered therethrough from the first processing chamber into the second processing chamber or from the second processing chamber into the first processing chamber, the pedestal is positioned in the second delivery port when the workpiece is processed in the second processing chamber, and the processing chamber cover includes a second transverse member extending from between the second side plate and the second delivery port both inwardly of the first processing chamber and inwardly of the second processing chamber.

In the processing apparatus according to the present invention, the processing chamber cover includes the first transverse member extending from between the first side plate and the first delivery port defined in the first side plate outwardly of the first processing chamber. In the processing apparatus, therefore, the width of a gap between the first transverse member and the pedestal positioned in the first delivery port when the workpiece is processed in the first processing chamber, i.e., the length of the gap along the direction toward the outside of the first processing chamber, is large.

When processing water that is scattered passes through the gap, it is highly probable for the processing water to contact the pedestal or the first transverse member and stay in the gap. As a result, the processing water is effectively prevented from being scattered out of the first processing chamber by a simple structure, compared with water supply means for forming a water film in the gap.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating an example of a processing apparatus for processing a workpiece in a processing chamber according to an embodiment of the present invention;

FIG. 2 is a perspective view schematically illustrating an example of a workpiece;

FIG. 3 is a plan view schematically illustrating a processing chamber cover, etc.;

FIG. 4A is a side elevational view, partly in cross section, schematically illustrating structural details of the processing chamber cover, etc., the cross section being taken along line 4A-4A of FIG. 3;

FIG. 4B is a side elevational view, partly in cross section, schematically illustrating structural details of the processing chamber cover, etc., the cross section being taken along line 4B-4B of FIG. 3;

FIG. 5 is a perspective view schematically illustrating another example of a processing apparatus for processing a workpiece in a processing chamber according to another embodiment of the present invention;

FIG. 6 is a perspective view schematically illustrating an example of a frame unit including the workpiece;

FIG. 7 is a plan view schematically illustrating a cassette placed on a cassette table, a delivery unit, a chuck table, a slide cover, a pedestal, a pair of cutting units, a spinner table, and a cleaning unit; and

FIG. 8 is a side elevational view, partly in cross section, schematically illustrating structural details of a processing chamber cover, etc., the cross section being taken along line 8-8 of FIG. 7.

### DETAILED DESCRIPTION OF THE PREFERRED EMBODIMENT

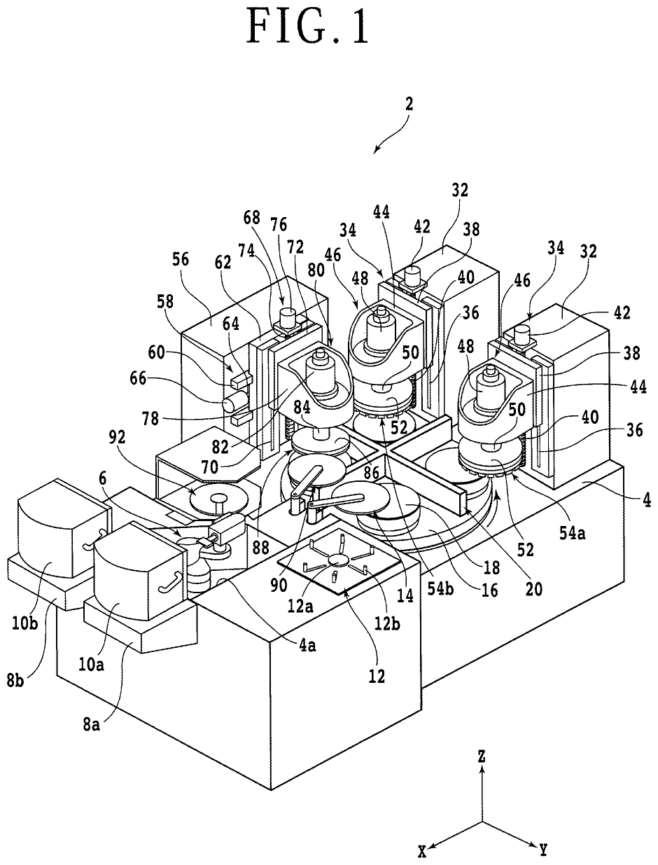

A preferred embodiment of the present invention will be described in detail below with reference to the accompanying drawings. FIG. 1 schematically illustrates, in perspective, an example of a processing apparatus for processing a workpiece in a processing chamber according to an embodiment of the present invention. Specifically, the processing apparatus illustrated in FIG. 1 is capable of rough grinding a workpiece in a rough grinding chamber, finish grinding the rough ground workpiece in a finish grinding chamber, and polishing the finish ground workpiece in a polishing chamber.

In FIG. 1, an X-axis direction, i.e., front-rear direction, indicated by an arrow X and a Y-axis direction, i.e., left-right direction, indicated by an arrow Y are directions orthogonal to each other on a horizontal plane. A Z-axis direction, i.e., top-down direction, indicated by an arrow Z is a direction, i.e., vertical direction, orthogonal to the X-axis direction and the Y-axis direction.

The processing apparatus, denoted by 2 in FIG. 1, has a base 4 on which various structural components are supported. The base 4 has an opening 4a defined in the upper surface of a front end portion thereof. A delivery unit 6 for delivering a plate-shaped workpiece is housed in the opening 4a.

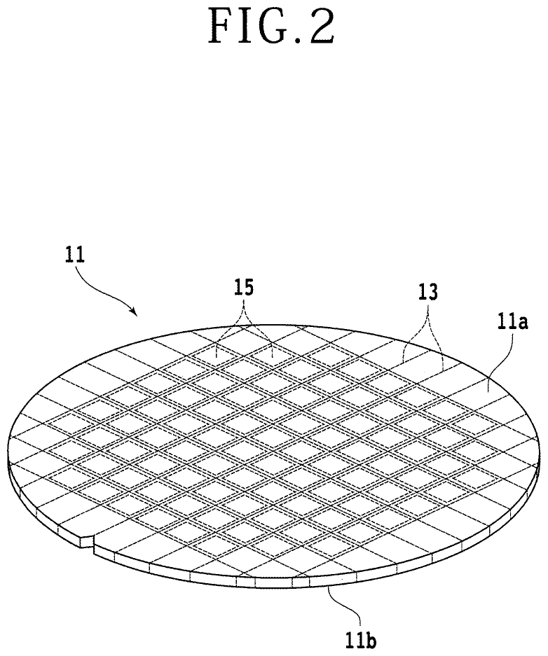

FIG. 2 schematically illustrates, in perspective, an example of a workpiece to be delivered by the delivery unit 6. The workpiece, denoted by 11 in FIG. 2, includes, for example, a wafer made of a semiconductor material such as silicon (Si) and having a circular face side 11a and a circular reverse side 11b. The workpiece 11 has a plurality areas demarcated on the face side 11a by a grid of projected dicing lines 13 and a plurality of devices 15 such as ICs constructed in the respective areas.

A film-shaped circular tape that is generally equal in diameter to the workpiece 11 may be affixed to the face side 11a of the workpiece 11. The tape which is made of resin, for example, serves to protect the devices 15 by reducing shocks applied to the face side 11a when the reverse side 11b of the workpiece 11 is ground.

The workpiece 11 is not limited to any particular materials, shapes, structures, sizes, etc. For example, the workpiece 11 may include a substrate made of other semiconductor materials, ceramic, resin, or metal. Similarly, the devices 15 are not limited to any particular kinds, numbers, shapes, structures, sizes, layouts, etc. The workpiece 11 may even be free of the devices 15.

As illustrated in FIG. 1, a pair of cassette tables 8a and 8b are mounted on the base 4 forwardly of the opening 4a. Cassettes 10a and 10b each for storing a plurality of workpieces 11 therein are placed respectively on the cassette tables 8a and 8b. A position adjusting mechanism 12 for adjusting the position of a workpiece 11 placed thereon is disposed on the base 4 obliquely rearwardly of the opening 4a.

The position adjusting mechanism 12 has, for example, a table 12a supporting a central region of the workpiece 11 and a plurality of pins 12b disposed around the table 12a at equal spaced intervals along circumferential direction of the table 12a. The pins 12b are radially movable toward and away from the table 12a for adjusting the distances between themselves and the table 12a. When the workpiece 11 is delivered from the cassette 10a, for example, and placed on the table 12a by the delivery unit 6, the pins 12b are moved toward the table 12a into contact with an outer circumferential edge of the workpiece 11, thereby bringing the workpiece 11 into coaxial alignment with the table 12a.

A loading unit 14 is disposed in the vicinity of the position adjusting mechanism 12. The loading unit 14 can be turned while holding the workpiece 11 delivered from the position adjusting mechanism 12. The loading unit 14 has a suction pad, not depicted, for attracting an upper surface of the workpiece 11 under suction. The loading unit 14 holds the workpiece 11 that has been adjusted in position by the position adjusting mechanism 12 and delivers the workpiece 11 rearwardly. A disk-shaped turntable 16 is disposed on an upper surface of the base 4 behind the loading unit 14.

The turntable 16 supports four chuck tables 18 angularly spaced circumferentially on an upper surface thereof. The chuck tables 18 can hold respective workpieces 11 under suction thereon when the workpieces 11 are processed on the processing apparatus 2. A criss-cross pedestal 20 that separates the four chuck tables 18 from each other is mounted on the upper surface of the turntable 16. The pedestal 20 has an upper surface positioned upwardly of the respective upper surfaces of the four chuck tables 18.

The turntable 16 is coupled to a rotary actuator, not depicted, such as an electric motor disposed in the base 4. When the rotary actuator is energized, the turntable 16, the four chuck tables 18, and the pedestal 20 are rotated in the direction indicated by the arrow in FIG. 1 about a straight rotational axis extending through the center of the upper surface of the turntable 16 parallel to the Z-axis direction.

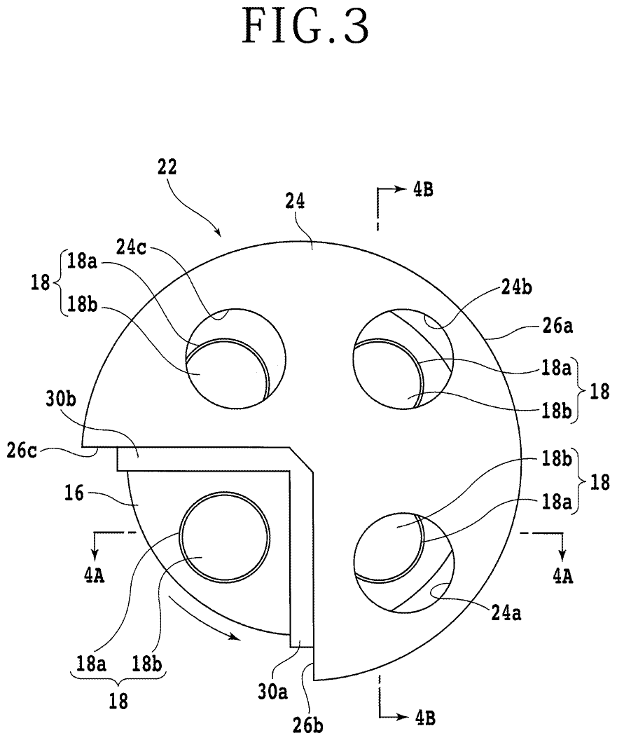

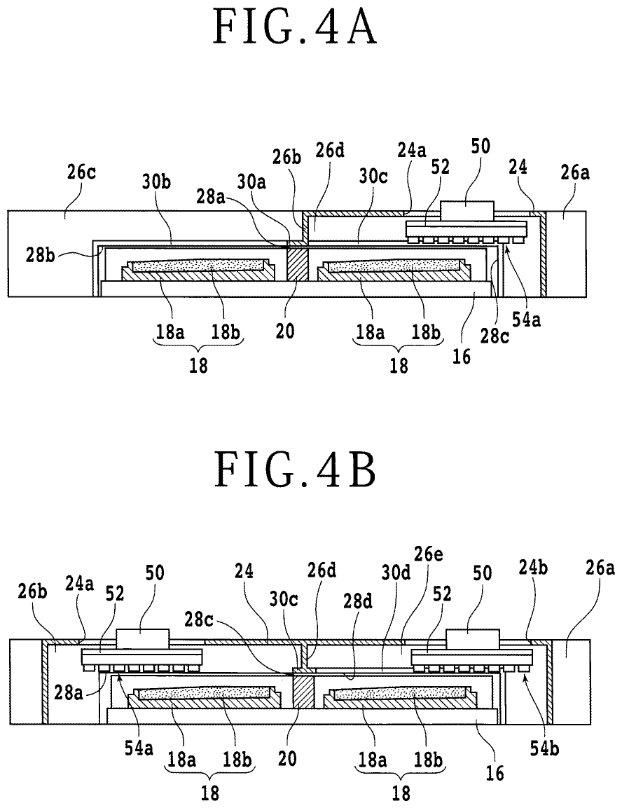

A processing chamber cover 22, not depicted in FIG. 1, is mounted on the upper surface of the base 4 in surrounding relation to the turntable 16, the four chuck tables 18, and the pedestal 20. FIG. 3 schematically illustrates the processing chamber cover 22, etc. in plan. FIG. 4A schematically illustrates, in side elevation, partly in cross section, the processing chamber cover 22, etc., the cross section being taken along line 4A-4A of FIG. 3. FIG. 4B schematically illustrates, in side elevation, partly in cross section, the processing chamber cover 22, etc., the cross section being taken along line 4B-4B of FIG. 3.

Each of the chuck tables 18 has a frame 18a shaped as a circular plate made of ceramic or the like. The frame 18a has a bottom wall shaped as a circular plate and a hollow cylindrical side wall erected from an outer circumferential portion of the bottom wall. The bottom wall and the side wall jointly define an upwardly open circular recess in an upper portion of the frame 18a. The bottom wall of the frame 18a has a fluid channel, not depicted, defined therein that is open at the bottom surface of the recess and fluidly connected to a suction source, not depicted, such as an ejector.

The recess defined in the upper portion of the frame 18a receives therein a porous plate 18b shaped as a circular plate having a diameter that is basically equal to the diameter of the recess. The porous plate 18b is made of porous ceramic, for example. The upper surface of the porous plate 18b and the upper surface of the side wall of the frame 18a are jointly shaped like a surface corresponding to a side surface of a cone, i.e., a surface whose center protrudes beyond an outer circumferential portion thereof.

When the suction source fluidly connected to the fluid channel defined in the bottom wall of the frame 18a is actuated, it generates a suction force that is transmitted through the fluid channel and the porous plate 18b and acts in a space near the upper surface of the porous plate 18b. Therefore, the upper surface of the porous plate 18b and the upper surface of the side wall of the frame 18a function as a holding surface of the chuck table 18 for holding the workpiece 11 under suction thereon. When the suction source is actuated while the workpiece 11 is placed on the holding surface of the chuck table 18, for example, the workpiece 11 is held under suction on the chuck table 18.

The processing chamber cover 22 has a top plate 24 shaped like three quadrants of a full circle as viewed in plan. The top plate 24 has a through hole 24a defined therein that is positioned under a rough grinding wheel 54a, to be described later, and is larger in diameter than the rough grinding wheel 54a, a through hole 24b defined therein that is positioned under a finish grinding wheel 54b, to be described later, and is larger in diameter than the finish grinding wheel 54b, and a through hole 24c defined therein that is positioned under a polishing pad 88, to be described later, and is larger in diameter than the polishing pad 88.

The processing apparatus 2 includes three processing chambers each provided below a quadrant region of the top plate 24 where one of the three through holes 24a, 24b, and 24c is defined. Specifically, a rough grinding chamber is provided below the quadrant region of the top plate 24 where the through hole 24a is defined. A finish grinding chamber is provided below the quadrant region of the top plate 24 where the through hole 24b is defined. A polishing chamber is provided below the quadrant region of the top plate 24 where the through hole 24c is defined.

Since the top plate 24 is shaped like three quadrants of a full circle, it leaves a quadrant space through which the turntable 16 is exposed. When one of the chuck tables 18 is positioned in the quadrant space, a workpiece 11 is loaded onto or unloaded from the chuck table 18 positioned in the quadrant space. The quadrant space is referred to as a loading and unloading zone.

The top plate 24 has an arcuate outer circumferential edge. A side panel 26a that extends arcuately as viewed in plan is provided below the arcuate outer circumferential edge of the top plate 24. The side panel 26a has a lower end fixed to the upper surface of the base 4. The side panel 26a has an upper end fixed to a lower side of the arcuate outer circumferential edge of the top plate 24. The side panel 26a has opposite ends to which respective ends of a pair of side plates 26b and 26c are connected.

The side plate 26b is positioned between the rough grinding chamber and the loading and unloading zone. The side plate 26c is positioned between the polishing chamber and the loading and unloading zone. The side plates 26b and 26c extend straight from the respective opposite ends of the side panel 26a toward the center of the top plate 24, as viewed in plan. The side plates 26b and 26c extend perpendicularly to each other as viewed in plan.

The side plates 26b and 26c have respective delivery ports 28a and 28b defined in lower portions thereof to allow the four chuck tables 18 and the pedestal 20 to move therethrough when the turntable 16 is rotated in the direction indicated by the arrow in FIG. 3. The side plates 26b and 26c have respective portions positioned outwardly of the respective delivery ports 28a and 28b and having respective lower ends fixed to the upper surface of the base 4.

The side plates 26b and 26c have respective upper ends fixed to lower sides of respective outer edges of the top plate 24 that extend straight as viewed in plan, other than the arcuate outer circumferential edge of the top plate 24. The side plate 26b has a portion lying over the delivery port 28a and a portion positioned outwardly of the delivery port 28a. A transverse member 30a that extends outwardly of the rough grinding chamber is joined to a lower end of the portion of the side plate 26b lying over the delivery port 28a and an inner end of the portion of the side plate 26b positioned outwardly of the delivery port 28a.

Similarly, the side plate 26c has a portion lying over the delivery port 28b and a portion positioned outwardly of the delivery port 28b. A transverse member 30b that extends outwardly of the polishing chamber is joined to a lower end of the portion of the side plate 26c lying over the delivery port 28b and an inner end of the portion of the side plate 26c positioned outwardly of the delivery port 28b. Stated otherwise, the processing chamber cover 22 includes the transverse members 30a and 30b extending from between the side plates 26b and 26c and the delivery ports 28a and 28b outwardly of the rough grinding chamber and the polishing chamber.

The other ends of the side plates 26b and 26c that are aligned with the center of the top plate 24 are coupled to respective ends of a pair of side plates 26d and 26e. The side plate 26d is positioned between the rough grinding chamber and the finish grinding chamber. The side plate 26e is positioned between the finish grinding chamber and the polishing chamber.

The side plate 26d extends from the other ends of the side plates 26b and 26c toward the side panel 26a perpendicularly to the side plate 26b, i.e., parallel to the side plate 26c. The side plate 26e extends from the other ends of the side plates 26b and 26c toward the side panel 26a parallel to the side plate 26b, i.e., perpendicularly to the side plates 26c and 26d.

The side plates 26d and 26e have respective delivery ports 28c and 28d defined in lower portions thereof to allow the four chuck tables 18 and the pedestal 20 to move therethrough when the turntable 16 is rotated in the direction indicated by the arrow in FIG. 3. The side plates 26d and 26e have respective portions positioned outwardly of the respective delivery ports 28c and 28d and having respective lower ends fixed to the upper surface of the base 4.

The side plates 26d and 26e have respective upper ends fixed to lower sides of the top plate 24. The side plate 26d has a portion lying over the delivery port 28c and a portion positioned outwardly of the delivery port 28c. A transverse member 30c that extends inwardly of the rough grinding chamber and inwardly of the finish grinding chamber is joined to a lower end of the portion of the side plate 26d lying over the delivery port 28c and an inner end of the portion of the side plate 26d positioned outwardly of the delivery port 28c.

Similarly, the side plate 26e has a portion lying over the delivery port 28d and a portion positioned outwardly of the delivery port 28d. A transverse member 30d that extends inwardly of the finish grinding chamber and inwardly of the polishing chamber is joined to a lower end of the portion of the side plate 26e lying over the delivery port 28d and an inner end of the portion of the side plate 26e positioned outwardly of the delivery port 28d. Stated otherwise, the processing chamber cover 22 includes the transverse members 30c and 30d extending from between the side plates 26d and 26e and the delivery ports 28c and 28d inwardly of a pair of adjacent processing chambers, i.e., the rough grinding chamber and the finish grinding chamber or the finish grinding chamber and the polishing chamber.

Workpieces 11 are rough ground, finish ground, and polished while the pedestal 20 is kept in facing relation to the four transverse members 30a, 30b, 30c and 30d. In other words, when the workpieces are rough ground, finish ground, and polished, the pedestal 20 is positioned in the four delivery ports 28a, 28b, 28c, and 28d.

The other structural components of the processing apparatus 2 will be described below with reference to FIG. 1. Two support structures 32 are mounted on the base 4 respectively rearwardly of the rough grinding chamber and the finish grinding chamber. Two Z-axis moving mechanisms 34 are mounted on respective front surfaces of the support structures 32. Since the two Z-axis moving mechanisms 34 are structurally identical to each other, only one of them will be described below. The Z-axis moving mechanism 34 has a pair of spaced guide rails 36 fixedly mounted on the front surface of the support structure 32 that faces the turntable 16 and extending along the Z-axis direction.

A movable plate 38 is slidably mounted on the guide rails 36 so as to face the turntable 16 for sliding movement along the guide rails 36. A screw shaft 40 extending along the Z-axis direction is disposed between the guide rails 36. The screw shaft 40 has an upper end coupled to an electric motor 42 that rotates the screw shaft 40 about its central axis.

The screw shaft 40 has an externally threaded surface threaded over a nut, not depicted, that houses a number of balls rollingly engaging the helical screw threads of the screw shaft 40. The screw shaft 40 and the nut with the balls jointly make up a ball screw mechanism. When the screw shaft 40 is rotated about its central axis by the electric motor 42, the balls circulate through the nut, causing the nut to move along the Z-axis direction.

The nut is fixed to a rear surface, i.e., a reverse side, of the movable plate 38 that faces the support structure 32. Therefore, when the electric motor 42 rotates the screw shaft 40 about its central axis, the movable plate 38 is moved together with the nut along the Z-axis direction. A support 44 is mounted on a front surface, i.e. a face side, of the movable plate 38 that faces the turntable 16.

The support 44 supports thereon a grinding unit, i.e., a processing unit, 46 for grinding a workpiece 11. The grinding unit 46 includes a spindle housing 48 fixed to the support 44. A spindle 50 extending along the Z-axis direction is rotatably housed in the spindle housing 48.

The spindle 50 has an upper end coupled to a rotary actuator, not depicted, such as an electric motor. When the rotary actuator is energized, it rotates the spindle 50 about its central axis. The spindle 50 has a lower end portion exposed from a lower surface of the spindle housing 48 and having a lower end to which a disk-shaped mount 52 is fixed.

A rough grinding wheel, i.e., a processing tool, 54a is mounted on a lower surface of the mount 52 of the grinding unit 46 that is provided on a side of the rough grinding chamber. The rough grinding wheel 54a has a circular wheel base that is generally equal in diameter to the mount 52. The wheel base is made of a metal material such as stainless streel or aluminum, for example.

The wheel base has a lower surface on which a plurality of grindstones containing abrasive grains suitable for rough grinding are fixedly mounted. The grindstones have respective lower surfaces, i.e., grinding surfaces, lying generally perpendicularly to the Z-axis direction, for rough grinding the workpiece 11 held under suction on the chuck table 18 that is positioned in the rough grinding chamber.

Similarly, a finish grinding wheel, i.e., a processing tool, 54b is mounted on a lower surface of the mount 52 of the grinding unit 46 that is provided on a side of the finish grinding chamber. The finish grinding wheel 54b has a circular wheel base that is generally equal in diameter to the mount 52. The wheel base is made of a metal material such as stainless streel or aluminum, for example.

The wheel base has a lower surface on which a plurality of grindstones containing abrasive grains suitable for finish grinding are fixedly mounted. The grindstones have respective lower surfaces, i.e., grinding surfaces, lying generally perpendicularly to the Z-axis direction, for finish grinding the workpiece 11 held under suction on the chuck table 18 that is positioned in the finish grinding chamber. The abrasive grains contained in the grindstones for finish grinding are generally smaller in diameter than those contained in the grindstones for rough grinding.

The processing apparatus 2 includes a first processing water supply unit, not depicted, for supplying processing water to at least one of the workpiece 11 or the grinding wheel 54a when the workpiece 11 is rough ground by the rough grinding wheel 54a in the rough grinding chamber and a second water supply unit, not depicted, for supplying processing water to at least one of the workpiece 11 or the finish grinding wheel 54b when the workpiece 11 is finish ground by the finish grinding wheel 54b in the finish grinding chamber.

Each of the first processing water supply unit and the second processing water supply unit has a nozzle, not depicted, for supplying processing water to a region, i.e., a processing point, of the workpiece 11 that is contacted by the grindstones, for example. Alternatively, each of the first processing water supply unit and the second processing water supply unit may have, in place of or in addition to the nozzle, a water channel defined in the grinding wheel 54a and 54b for supplying processing water to the processing point.

Another support structure 56 is mounted on the base 4 alongside of the polishing chamber. An X-axis moving mechanism 58 is mounted on a side surface of the support structure 56. The X-axis moving mechanism 58 has a pair of spaced guide rails 60 fixedly mounted on the side surface of the support structure 56 that faces the turntable 16 and extending along the X-axis direction.

A movable plate 62 is slidably mounted on the guide rails 60 so as to face the turntable 16 for sliding movement along the guide rails 60. A screw shaft 64 extending along the X-axis direction is disposed between the guide rails 60. The screw shaft 64 has a front end coupled to an electric motor 66 that rotates the screw shaft 64 about its central axis.

The screw shaft 64 has an externally threaded surface threaded over a nut, not depicted, that houses a number of balls rollingly engaging the helical screw threads of the screw shaft 64. The screw shaft 64 and the nut with the balls jointly make up a ball screw mechanism. When the screw shaft 64 is rotated about its central axis by the electric motor 66, the balls circulate through the nut, causing the nut to move along the X-axis direction.

The nut is fixed to a surface, i.e., a reverse side, of the movable plate 62 that faces the support structure 56. Therefore, when the electric motor 66 rotates the screw shaft 64 about its central axis, the movable plate 62 is moved together with the nut along the X-axis direction. A Z-axis moving mechanism 68 is mounted on a surface, i.e., a face side, of the movable plate 62 that faces the turntable 16.

The Z-axis moving mechanism 68 has a pair of spaced guide rails 70 fixedly mounted on the face side of the movable plate 62 and extending along the Z-axis direction. A movable plate 72 is slidably mounted on the guide rails 70 so as to face the turntable 16 for sliding movement along the guide rails 70.

A screw shaft 74 extending along the Z-axis direction is disposed between the guide rails 70. The screw shaft 74 has an upper end coupled to an electric motor 76 that rotates the screw shaft 74 about its central axis. The screw shaft 74 has an externally threaded surface threaded over a nut, not depicted, that houses a number of balls rollingly engaging the helical screw threads of the screw shaft 74. The screw shaft 74 and the nut with the balls jointly make up a ball screw mechanism.

When the screw shaft 74 is rotated about its central axis by the electric motor 76, the balls circulate through the nut, causing the nut to move along the Z-axis direction. The nut is fixed to a surface, i.e., a reverse side, of the movable plate 72 that faces the movable plate 62. Therefore, when the electric motor 76 rotates the screw shaft 74 about its central axis, the movable plate 72 is moved together with the nut along the Z-axis direction.

A support 78 is mounted on a surface, i.e. a face side, of the movable plate 72 that faces the turntable 16. The support 78 supports thereon a polishing unit, i.e., a processing unit, 80 for polishing a workpiece 11. The polishing unit 80 includes a spindle housing 82 fixed to the support 78.

A spindle 84 extending along the Z-axis direction is rotatably housed in the spindle housing 82. The spindle 84 has an upper end coupled to a rotary actuator, not depicted, such as an electric motor. When the rotary actuator is energized, it rotates the spindle 84 about its central axis.

The spindle 84 has a lower end portion exposed from a lower surface of the spindle housing 82 and having a lower end to which a disk-shaped mount 86 is fixed. A disk-shaped polishing pad, i.e., a processing tool, 88 is mounted on a lower surface of the mount 86. The polishing pad 88 is larger in diameter than the workpiece 11 held under suction on the chuck table 18 in the polishing chamber, for example.

The polishing pad 88 has a circular lower surface, i.e., a polishing surface, lying generally perpendicularly to the Z-axis direction, for polishing in a wet environment the workpiece 11 held under suction on the chuck table 18 that is positioned in the polishing chamber. The polishing pad 88 is fabricated by impregnating a piece of nonwoven fabric made of polyester with a solution of urethane in which abrasive grains having an average particle diameter of 20 μm or less are dispersed and then drying the impregnated piece of nonwoven fabric, for example.

The abrasive grains that are dispersed in the polishing pad 88 are made of a material such as silicon carbide, cBN, diamond, or fine particulate metal oxide. The fine particulate metal oxide may be in the form of fine particles of silica, ceria, zirconia, alumina, or the like. The polishing pad 88 is pliable, and can slightly flex under a load applied when it polishes the workpiece 11.

The processing apparatus 2 also includes a third processing water supply unit, not depicted, for supplying processing water to at least one of the workpiece 11 or the polishing pad 88 when the workpiece 11 is polished by the polishing pad 88 in the polishing chamber.

The third processing water supply unit has a nozzle, not depicted, for supplying processing water to a region, i.e., a processing point, of the workpiece 11 that is contacted by the polishing pad 88, for example. Alternatively, the third processing water supply unit may have, in place of or in addition to the nozzle, a water channel defined in the polishing pad 88 for supplying processing water to the processing point.

An unloading unit 90 is disposed laterally of the loading unit 14. The unloading unit 90 can be turned while holding a workpiece 11 delivered from the chuck table 18 positioned in the loading and unloading zone. The unloading unit 90 unloads the workpiece 11 forwardly from the loading and unloading zone by turning away from the loading and unloading zone while holding the workpiece 11 that has been polished in the polishing chamber, for example.

A cleaning unit 92 for cleaning the workpiece 11 unloaded from the loading and unloading zone by the unloading unit 90 is disposed forwardly of the unloading unit 90 and rearwardly of the opening 4a. The workpiece 11 that has been cleaned by the cleaning unit 92 is delivered by the delivery unit 6 and stored in the cassette 10b, for example.

In the processing apparatus 2, the processing chamber cover 22 includes the transverse members 30a and 30b extending from between the side plates 26b and 26c and the delivery ports 28a and 28b defined in the side plates 26b and 26c outwardly of the processing chambers, i.e., the rough grinding chamber and the polishing chamber. In the processing apparatus 2, the workpieces 11 are processed, i.e., rough ground and polished, while the pedestal 20 and the transverse members 30a and 30b are facing each other.

Consequently, the widths of gaps between the pedestal 20 and the transverse members 30a and 30b, i.e., the lengths of the gaps along the directions toward the outside of the processing chambers, are large. When the processing water that is scattered passes through the gaps, it is highly probable for the processing water to contact the pedestal 20 or the transverse members 30a and 30b and stay in the gaps.

As a result, the processing water is effectively prevented from being scattered out of the processing chambers by a simple structure including the pedestal 20 and the transverse members 30a and 30b, compared with water supply means for forming water films in the gaps. In the processing apparatus 2, water films may be created by the processing water staying in the gaps. Such water films are effective to prevent the processing water from being scattered out of the processing chambers.

In the processing apparatus 2, the processing chamber cover 22 also includes the transverse members 30c and 30d joined to the ends of the side plates 26d and 26e that are close to the delivery ports 28c and 28d defined therein. The transverse members 30c and 30d extend inwardly of a pair of adjacent processing chambers, i.e., the rough grinding chamber and the finish grinding chamber or the finish grinding chamber and the polishing chamber.

In the processing apparatus 2, the workpieces 11 are processed, i.e., rough ground, finish ground, and polished, while the pedestal 20 and the transverse members 30c and 30d are facing each other. In the processing apparatus 2, therefore, the processing water is prevented from being scattered from a processing chamber, e.g., the rough grinding chamber, into another adjacent processing chamber, e.g., the finish grinding chamber, as described above.

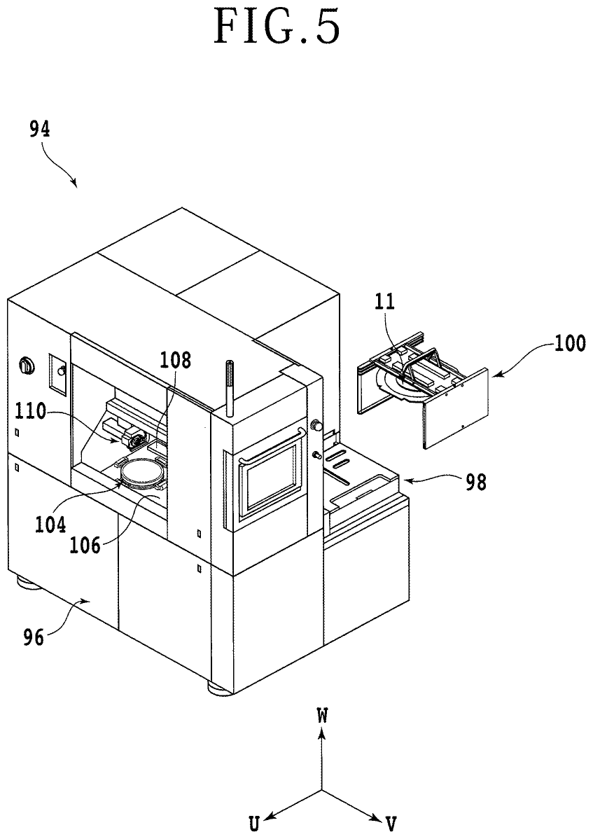

FIG. 5 schematically illustrates, in perspective, another example of a processing apparatus for processing a workpiece in a processing chamber according to another embodiment of the present invention. Specifically, the processing apparatus illustrated in FIG. 5 is a cutting apparatus capable of cutting a workpiece in a cutting chamber.

In FIG. 5, a U-axis direction, i.e., front-rear direction or processing feed direction, indicated by the arrow U and a V-axis direction, i.e., left-right direction or indexing feed direction, indicated by the arrow V are directions orthogonal to each other on a horizontal plane. A W-axis direction, i.e., top-down direction, indicated by the arrow W is a direction, i.e., vertical direction, orthogonal to the U-axis direction and the V-axis direction.

The cutting apparatus, denoted by 94 in FIG. 5, has a base 96 on which various structural components are supported. A cassette table 98 is disposed on a corner of the base 96. The cassette table 98 has an upper surface on which a cassette 100 for housing a frame unit including a workpiece 11 can be placed.

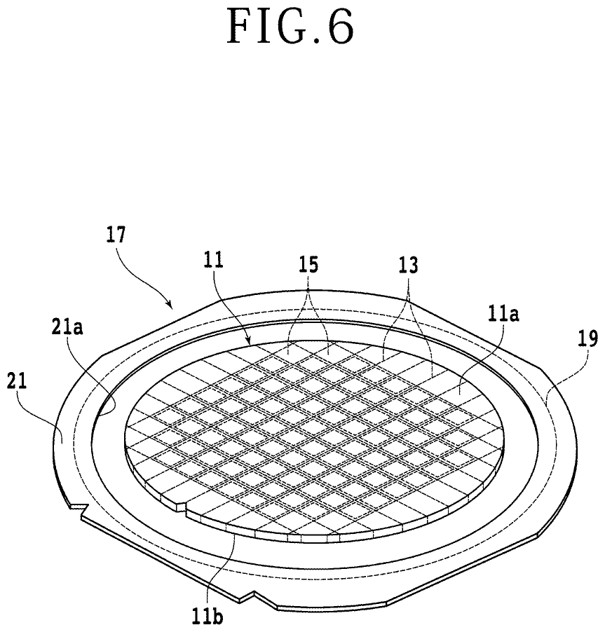

FIG. 6 schematically illustrates, in perspective, an example of the frame unit including the workpiece 11. The frame unit is denoted by 17 in FIG. 6, and the workpiece 11 included in the frame unit 17 is identical to the workpiece 11 illustrated in FIG. 2. The frame unit 17 includes a support member 19 shaped as a circular plate that is larger in diameter than the workpiece 11. The support member 19 has a central region affixed to the reverse side 11b of the workpiece 11.

The support member 19 has a film-like flexible base layer and an adhesive layer, i.e., a glue layer, attached to a surface, i.e., a surface facing the workpiece 11, of the base layer. Specifically, the base layer is made of polyolefin (PO), polypropylene (PP), polyethylene terephthalate (PET), polyvinyl chloride (PVC), polystyrene (PS), or the like. The adhesive layer is made of ultraviolet-curable silicone rubber, an acryl-based material, an epoxy-based material, or the like.

The frame unit 17 also includes an annular frame 21 affixed to an outer circumferential portion of the support member 19. A circular opening 21a that is larger in diameter than the workpiece 11 is formed in the annular frame 21. The annular frame 21 is made of a metal material such as aluminum or stainless steel.

The cassette table 98 illustrated in FIG. 5 is coupled to a W-axis moving mechanism, not depicted. The W-axis moving mechanism operates to adjust the height of the cassette 100 placed on the cassette table 98 in order to allow the frame unit 17 to be appropriately loaded and unloaded, as described later.

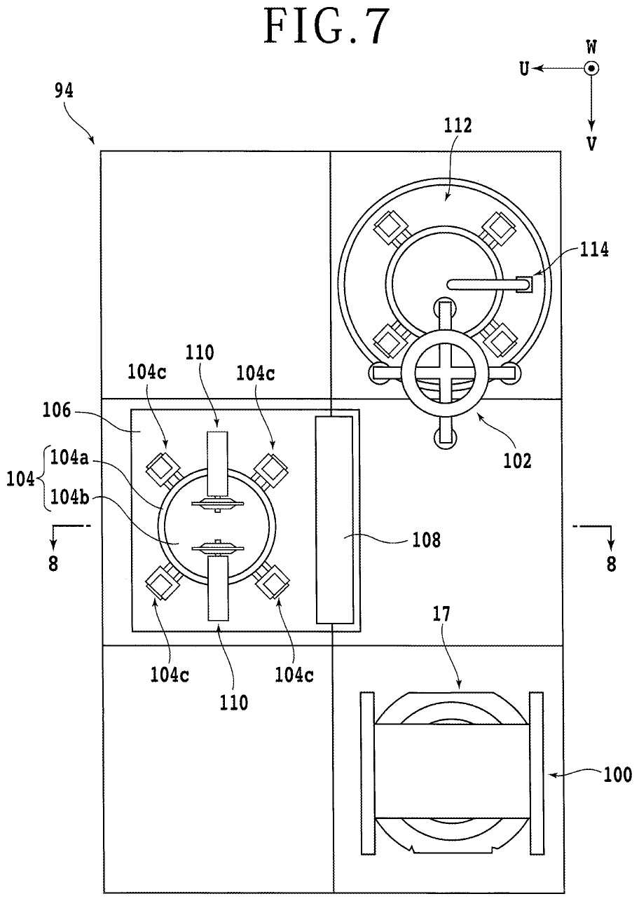

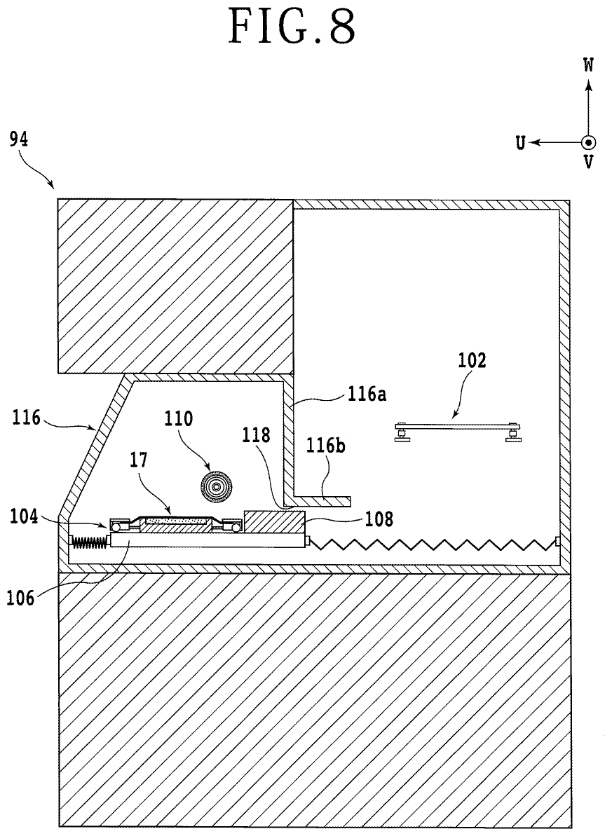

As illustrated in FIGS. 7 and 8, the cutting apparatus 94 includes, above the base 96, a delivery unit 102, a chuck table 104 (see also FIG. 5), a slide cover 106 (see also FIG. 5), a pedestal 108 (see also FIG. 5), a pair of cutting units, i.e., processing units, 110 (see also FIG. 5), a spinner table 112, and a cleaning unit 114. The cutting apparatus 94 also includes a cutting chamber cover, i.e., a processing chamber cover, 116 mounted on the base 96 in surrounding relation to the chuck table 104, the slide cover 106, the pedestal 108, and the cutting units 110.

FIG. 7 schematically illustrates, in plan, the cassette 100 on the cassette table 98, the delivery unit 102, the chuck table 104, the slide cover 106, the pedestal 108, the cutting units 110, the spinner table 112, and the cleaning unit 114. FIG. 8 schematically illustrates, in side elevation, partly in cross section, structural details of the cutting chamber cover 116, etc., the cross section being taken along line 8-8 of FIG. 7.

The delivery unit 102 is coupled to a V-axis moving mechanism, not depicted, and the W-axis moving mechanism, not depicted. The V-axis moving mechanism operates to move the delivery unit 102 from a region above the spinner table 112 to a region near the cassette 100 placed on the cassette table 98.

The W-axis moving mechanism operates to adjust the height of the delivery unit 102 in order to allow the frame unit 17 to be appropriately loaded onto the spinner table 112 by the delivery unit 102 or appropriately unloaded from the spinner table 112 by the delivery unit 102. The delivery unit 102 has a gripper, not depicted, for gripping the annular frame 21 of the frame unit 17 and a suction pad for attracting an upper surface of the annular frame 21 under suction.

The chuck table 104 is coupled to a U-axis moving mechanism, not depicted, and a rotary actuator, not depicted. The U-axis moving mechanism operates to move the chuck table 104 from the cutting chamber that is surrounded by the cutting chamber cover 116 to a zone between the cassette table 98 and the spinner table 112.

The zone between the cassette table 98 and the spinner table 112 is also referred to as a loading and unloading zone. When the rotary actuator coupled to the chuck table 104 is energized, it rotates the chuck table 104 about a straight rotational axis extending through the center of the upper surface of the chuck table 104 along the W-axis direction.

The chuck table 104 has a frame 104a shaped as a circular plate and made of ceramic or the like. The frame 104a has a bottom wall shaped as a circular plate and a hollow cylindrical side wall erected from an outer circumferential portion of the bottom wall. The bottom wall and the side wall jointly define an upwardly open circular recess in an upper portion of the frame 104a.

The bottom wall of the frame 104a has a fluid channel, not depicted, defined therein that is open at the bottom surface of the recess and fluidly connected to a suction source, not depicted, such as an ejector. The recess defined in the upper portion of the frame 104a receives therein a porous plate 104b shaped as a circular plate having a diameter that is basically equal to the diameter of the recess. The porous plate 104b is made of porous ceramic, for example.

When the suction source fluidly connected to the fluid channel defined in the bottom wall of the frame 104a is actuated, it generates a suction force that is transmitted through the fluid channel and the porous plate 104b and acts in a space near the upper surface of the porous plate 104b. Therefore, the upper surface of the porous plate 104b and the upper surface of the side wall of the frame 104a function as a holding surface of the chuck table 104 for holding the frame unit 17 under suction thereon. When the suction source is actuated while the frame unit 17 is placed on the holding surface of the chuck table 104, for example, the workpiece 11 is held under suction on the chuck table 104 with the support member 19 interposed therebetween.

There are four clamps 104c disposed around the frame 104a at generally equal angular intervals along circumferential direction of the frame 104a. Each of the four clamps 104c holds the annular frame 21 at positions lower than the holding surface of the chuck table 104 when the chuck table 104 holds the workpiece 11 on the holding surface.

The slide cover 106 is disposed around the chuck table 104 and movable together with the chuck table 104 along the U-axis direction. The pedestal 108 is positioned behind the chuck table 104 and fixed to an upper surface of the slide cover 106. The pedestal 108 extends along the V-axis direction and has an upper surface positioned upwardly of the upper surface of the chuck table 104.

Each of the cutting units 110 is coupled to a V-axis moving mechanism, not depicted, and a W-axis moving mechanism, not depicted. The V-axis moving mechanism operates to move the cutting unit 110 along the V-axis direction in the cutting chamber. The W-axis moving mechanism operates to move the cutting unit 110 along the W-axis direction in the cutting chamber.

Each of the cutting units 110 has a spindle extending along the V-axis direction. A cutting blade, i.e., a processing tool, is mounted on a distal end of the spindle. The spindle has a proximal end coupled to a rotary actuator, not depicted, such as an electric motor. When the rotary actuator is energized, the spindle and hence the cutting blade are rotated about a straight rotational axis extending along the V-axis direction.

A processing water supply unit, not depicted, is disposed near each of the cutting units 110 for supplying processing water to at least one of the workpiece 11 or the cutting blade when the workpiece 11 is cut by the cutting unit 110 in the cutting chamber. The processing water supply unit has a nozzle, not depicted, for supplying processing water to a region, i.e., a processing point, of the workpiece 11 that is contacted by the cutting blade, for example.

The spinner table 112 is coupled to a rotary actuator, not depicted. When the rotary actuator is energized, it rotates the spinner table 112 about a straight rotational axis extending through the center of the upper surface of the spinner table 112 parallel to the W-axis direction. The spinner table 112 is identical in structure to the chuck table 104 and will not be described in detail below.

The cleaning unit 114 has a pipe-shaped shaft, not depicted, extending along the W-axis direction. The pipe-shaped shaft has a lower end coupled to a rotary actuator, not depicted, such as an electric motor for rotating the pipe-shaped shaft. The pipe-shaped shaft has an upper end to which an arm is connected.

The arm includes a pipe-shaped member extending in a direction perpendicular to the W-axis direction and having a length commensurate with the distance from the upper end of the pipe-shaped shaft to the center of the upper surface of the spinner table 112. The arm has a distal end remote from the pipe-shaped shaft, the distal end having a cleaning nozzle, not depicted, for discharging cleaning water downwardly.

The pipe-shaped shaft is in fluid communication with a cleaning water supply source, not depicted, that supplies cleaning water to the pipe-shaped shaft. When the cleaning water supply source supplies cleaning water to the pipe-shaped shaft and the arm after the pipe-shaped shaft has been turned to position the cleaning nozzle above the spinner table 112, the cleaning nozzle supplies the cleaning water from the arm to the upper surface of the spinner table 112.

The cutting chamber cover 116 has a side plate 116a positioned between the cutting chamber and the loading and unloading zone. The side plate 116a has a delivery port 118 defined in a lower portion thereof to allow the chuck table 104, the slide cover 106, and the pedestal 108 to move therethrough along the U-axis direction.

A transverse member 116b that extends outwardly of the cutting chamber is joined to a lower end of the side plate 116a. Stated otherwise, the cutting chamber cover 116 includes the transverse member 116b extending from between the side plate 116a and the delivery port 118 outwardly of the cutting chamber.

In the cutting apparatus 94, as described above, the cutting chamber cover 116 includes the transverse member 116b extending from between the side plate 116a and the delivery port 118 outwardly of the cutting chamber. The cutting apparatus 94 cuts the workpiece 11 on the chuck table 104 while the upper surface of the pedestal 108 and the lower surface of the transverse member 116b are facing each other.

Consequently, the width of a gap between the pedestal 108 and the transverse member 116b, the length of the gap along the direction toward the outside of the cutting chamber, is large. When the processing water that is scattered passes through the gap, it is highly probable for the processing water to contact the pedestal 108 or the transverse member 116b and stay in the gap.

As a result, in the cutting apparatus 94, the processing water is effectively prevented from being scattered out of the cutting chamber by a simple structure, compared with water supply means for forming a water film in the gap. In addition, a water film may be created by the processing water staying in the gap. Such a water film is effective to prevent the processing water from being scattered out of the cutting chamber.

The structural and processing details according to the above embodiment has been illustrated by way of example only. Various many changes and modifications may be made therein without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing apparatus for processing a workpiece in a first processing chamber, comprising:
a chuck table for holding the workpiece thereon;
a processing chamber cover having a first side plate with a first delivery port defined therein to allow the chuck table that is holding the workpiece to be delivered therethrough into and out of the first processing chamber;
a first processing unit for processing the workpiece delivered into the first processing chamber with a first processing tool;
a first processing water supply unit for supplying first processing water to at least one of the workpiece or the first processing tool when the workpiece is processed in the first processing chamber; and
a pedestal positioned in the first delivery port when the workpiece is processed in the first processing chamber,
wherein the processing chamber cover includes a first transverse member extending from between the first side plate and the first delivery port outwardly of the first processing chamber.

2. The processing apparatus according to claim 1, for processing the workpiece in a second processing chamber in addition to the first processing chamber, further comprising:
a second processing unit for processing the workpiece delivered into the second processing chamber with a second processing tool; and
a second processing water supply unit for supplying second processing water to at least one of the workpiece or the second processing tool when the workpiece is processed in the second processing chamber,
wherein the processing chamber cover has a second side plate with a second delivery port defined therein to allow the chuck table that is holding the workpiece to be delivered therethrough from the first processing chamber into the second processing chamber or from the second processing chamber into the first processing chamber,
the pedestal is positioned in the second delivery port when the workpiece is processed in the second processing chamber, and
the processing chamber cover includes a second transverse member extending from between the second side plate and the second delivery port both inwardly of the first processing chamber and inwardly of the second processing chamber.
